(19) United States
(12) Patent Application Publication
(10) Pub. No.: US 2013/0299852 A1
(43) Pub. Date: Nov. 14, 2013

(54) SUBSTRATE FOR OPTICAL SEMICONDUCTOR APPARATUS, METHOD FOR MANUFACTURING THE SAME, OPTICAL SEMICONDUCTOR APPARATUS, AND METHOD FOR MANUFACTURING THE SAME

(71) Applicant: SHIN-ETSU CHEMICAL CO., LTD., Tokyo (JP)

(72) Inventors: Satoshi ONAI, Takasaki (JP); Mitsuhiro IWATA, Takasaki (JP); Yoshifumi HARADA, Takasaki (JP); Shinji KIMURA, Annaka (JP)

(73) Assignee: SHIN-ETSU CHEMICAL CO., LTD., Tokyo (JP)

(21) Appl. No.: 13/871,336

(22) Filed: Apr. 26, 2013

(30) Foreign Application Priority Data
May 14, 2012 (JP) 2012-110954

(51) Int. Cl. H01L 33/56; H01L 33/08

(52) U.S. Cl. CPC H01L 33/56; H01L 33/08
USPC 257/88; 438/28

(57) ABSTRACT

The present invention provides a substrate for an optical semiconductor apparatus for mounting optical semiconductor devices, the substrate comprising first leads to be electrically connected to first electrodes of the optical semiconductor devices and second leads to be electrically connected to second electrodes of the optical semiconductor devices, wherein the first leads and the second leads are arranged each in parallel, a molded body of a thermosetting resin composition is molded by injection molding in a penetrating gap between the first leads and the second leads such that the substrate is formed in a plate shape, and an exposed front surface and an exposed back surface of the first leads, the second leads and the resin molded body each tie in a same plane. The substrate exhibits excellent heat dissipation properties and enables manufacture of a thin optical semiconductor apparatus with a low cost.

### BACKGROUND OF THE INVENTION

1. Field of the Invention

The present invention relates to a substrate for an optical semiconductor apparatus suitable for mounting an optical semiconductor device such as LED and a method for manufacturing the substrate, an optical semiconductor apparatus using the substrate, and a method for manufacturing the apparatus.

2. Description of the Related Art

An optical semiconductor device such as LED has excellent characteristics of less electric power consumption, so that the applications of the optical semiconductor devices for exterior illumination and automobile are increasing in recent years. An optical semiconductor apparatus manufactured by lens-molding a substrate on which an optical semiconductor device has been mounted is generally used for exterior illumination and automobiles. On the other hand, there is a trial calculation that the surface temperature of the optical semiconductor devices at the time of driving reaches to 150° C. due to increase in a heating value from the optical semiconductor devices which became highly luminance still more. In such a situation, it is particularly important to select the materials for the substrate for an optical semiconductor apparatus and its heat dissipation properties to improve characteristics and lifetime of the optical semiconductor apparatus.

A substrate having a multilayer of ceramic and metal has generally been used as a mounted substrate for a lens molded optical semiconductor apparatus in the viewpoint of excellent heat dissipation properties (for example, see Patent Document 1 and Patent Document 2). A substrate manufactured by laminating a ceramic material with a metal plate and molding it with good thickness precision is an expensive material in processing cost and material cost since processability and moldability of ceramic are poor. In addition, a ceramic substrate is manufactured by a firing process so that it is difficult to realize high-dimensional accuracy, and from this reason, it is difficult to advance reducing the thickness.

Moreover, the ceramic substrate has the advantages of high hardness and high heat dissipation, but it has a defect that it is fragile; and there arises a problem in that the ceramic substrate breaks due to clamp pressure by the mold in the molding machine when lens-molding is carried out.

Also, there is a method in which optical semiconductor devices are mounted onto a flat-package substrate arranged in a matrix state, and the substrate is then divided into pieces to obtain an optical semiconductor apparatus, but it is difficult to actually prepare the flat-package substrate arranged in a matrix state by using a ceramic material because of the various problems mentioned above. In addition, in a dicing process for dividing the flat-package substrate arranged in a matrix state into each device, a long processing time for cutting very hard ceramic is makes the process inefficient, and further the dicing blade easy to be markedly consumed, so that use of this substrate has industrial disadvantage.

When an optical semiconductor apparatus is manufactured by using a ceramic substrate as mentioned above, there are many problems in the points of the cost of the ceramic substrate itself, dimensional accuracy, operatability of the substrate in the manufacturing process, economical efficiency in the process of manufacturing an optical semiconductor apparatus from the substrate, so that it has been required to develop a substrate for an optical semiconductor apparatus which can be industrially manufactured with a low cost, and has excellent in heat dissipation properties and is capable of reducing the thickness.

### CITATION LIST

### Patent Literature

[Patent Document 1] Japanese Unexamined Patent publication (Kokai) No. 2011-071554
[Patent Document 2] Japanese Unexamined Patent publication (Kokai) No. 2011-181550
[Patent Document 3] Japanese Patent No. 4608294
[Patent Document 4] Japanese Unexamined Patent publication (Kokai) No. 2007-235085
[Patent Document 5] Japanese Unexamined Patent publication (Kokai) No. 2011-009519
[Patent Document 6] Japanese Unexamined Patent publication (Kokai) No. 2011-222870

### SUMMARY OF THE INVENTION

As a substrate for an optical semiconductor apparatus substitute for the ceramic substrate, it has been proposed a substrate for an optical semiconductor apparatus in which a thermosetting resin composition layer for light reflection is formed by transfer molding on a lead frame substrate manufactured by processing a metal having good thermal conductivity (for example, see Patent Documents 3 to 5).

According to this method, however, a resin layer (reflector) having a cup shape (concave shape) is required to be formed by transfer molding, and the reflector is extremely disadvantageous to reduce the thickness of the optical semiconductor apparatus by carrying out lens molding. More specifically, the reflector becomes a hindrance in the flow passage of a lens material when the lens molding is carried out, causing failure during molding: e.g., bubbles are easy to be generated in the interior of the lens, or unfilling of the lens material occurs. In addition, as well-known in the art, in the transfer molding, a cured resin called “cull”, which is not required in products, is formed with a large amount at the resin flow passage of the mold during molding so that it is uneconomical.

On the other hand, it has been proposed a surface-mount substrate for an optical semiconductor apparatus having a substantially flat shaped structure in which a resin composition is filled and cured in a gap between first leads for mounting optical semiconductor devices and second leads electrically connected with the optical semiconductor devices without forming the above concave-shaped reflector (for example, see Patent Document 6). However, according to this method, its steps are complicated and there are many industrial problems such as product precision, production cost, productivity, etc.

The surface mount substrate for an optical semiconductor apparatus with a substantially flat shaped structure without a reflector structure is sometimes called as a flat frame.

For manufacturing the flat frame, when a molded body of a thermosetting resin composition is molded to the gap between the above-mentioned first leads and second leads by transfer molding, since the flow passage of the thermosetting resin composition has a height corresponding to the thickness of the lead and a width corresponding to a very narrow gap between the leads, an unfilling portion (or air remaining) in the resin molded body is generated; thus a good molded product cannot be obtained. On the other hand, when a pressure for pressing the resin during molding is increased to inhibit the generation of the unfilling portion and air remaining, a resin burr (flash burr) of a thin film is generated, which is caused by entering the resin into a very narrow gap between the leads and the upper and lower molds.

The resin flash contaminates the lead surface to be utilized for wire bonding connection of the optical semiconductor devices, causing failure such as an inability to electrically connect the optical semiconductor devices with the leads. Moreover, the resin burr lowers reflection efficiency of light emitted from the optical semiconductor apparatus, so that an optical semiconductor apparatus having high luminance cannot be manufactured stably.

The present invention has been accomplished in view of the above-mentioned problems, and its object is to provide a substrate for an optical semiconductor apparatus employing a structure excellent in heat dissipation properties which uses a metal lead, and enabling reduction in the thickness of the optical semiconductor apparatus, a method for manufacturing the substrate for an optical semiconductor apparatus readily with a low cost, an optical semiconductor apparatus using the substrate and a method for manufacturing the apparatus.

To accomplish the above-mentioned object, the present invention provides a substrate for an optical semiconductor apparatus for mounting optical semiconductor devices, the substrate comprising first leads to be electrically connected to first electrodes of the optical semiconductor devices and second leads to be electrically connected to second electrodes of the optical semiconductor devices, wherein the first leads and the second leads are arranged each in parallel, a molded body of a thermosetting resin composition is molded by injection molding in a penetrating gap between the first leads and the second leads such that the substrate is formed in a plate shape, and an exposed front surface and an exposed back surface of the first leads, the second leads and the resin molded body each tie in a same plane.

Such a substrate for an optical semiconductor apparatus is low-cost and has excellent heat dissipation properties and high quality without the generation of an unfilled portion and a resin burr in the resin molded body. Moreover, this plate shaped substrate for an optical semiconductor apparatus enables fabrication of a thin optical semiconductor apparatus.

In the substrate, metal plating is preferably applied onto surfaces of the first leads and the second leads.

Such a substrate has high reflectivity.

Moreover, the first leads and the second leads preferably each have a step, a taper portion or a concave portion at their side surfaces in a thickness direction.

With the leads having such a constitution, the thermosetting resin composition can be held more surely in the gap during the injection molding so that the substrate can be readily manufactured. Also, the strength of the substrate can be improved.

Moreover, the first leads and the second leads arranged each in parallel can be connected to a frame-shaped frame through a tie bar having a thickness thinner than the thicknesses of the first leads and the second leads.

With the leads having such a constitution, it can be readily handled during the injection molding, and the generation of an unfilled portion and a resin burr in the resin molded body near the tie bar can be reduced.

The thermosetting resin composition may be at least one selected from the group consisting of a silicone resin, an organic modified silicone resin, an epoxy resin, a modified epoxy resin, an acrylate resin and an urethane resin.

Such a substrate has excellent heat resistance.

The cured thermosetting resin contains at least one of an inorganic filler and a diffusing agent, the inorganic filler may be at least one selected from the group consisting of silica, alumina, magnesium oxide, antimony oxide, aluminum hydroxide, barium sulfate, magnesium carbonate and barium carbonate, and the diffusing agent may be at least one selected from the group consisting of barium titanate, titanium oxide, aluminum oxide and silicon oxide.

Such a substrate is excellent in heat resistance, weather resistance and light resistance.

Furthermore, the present invention provides an optical semiconductor apparatus comprising an optical semiconductor device mounted on a first lead of the above substrate for an optical semiconductor apparatus of the present invention, a first electrode and a second electrode of the optical semiconductor device are electrically connected to the first lead and a second lead, respectively, by wire bonding or flip chip bonding, and the optical semiconductor device is sealed by a resin or subjected to lens molding.

Such an optical semiconductor apparatus is low-cost and has excellent heat dissipation properties and high quality without the generation of an unfilled portion and a resin burr in the resin molded body. Moreover, when the optical semiconductor apparatus having the lens molded optical semiconductor devices is thin.

Furthermore, the present invention provides a method for manufacturing a substrate for an optical semiconductor apparatus for mounting optical semiconductor devices, the substrate including first leads to be electrically connected to first electrodes of the optical semiconductor devices and second leads to be electrically connected to second electrodes of the optical semiconductor devices, the method comprising arranging the first leads and the second leads each in parallel, and molding a molded body of a thermosetting resin composition by injection molding in a penetrating gap between the first leads and the second leads such that an exposed front surface and an exposed back surface of the first leads, the second leads and the resin molded body each tie in a same plane and the substrate is formed in a plate shape.

By such a manufacturing method, a substrate for an optical semiconductor apparatus that has excellent heat dissipation properties and high quality without the generation of an unfilled portion and a resin burr in the resin molded body and enables fabrication of a thin optical semiconductor apparatus can be readily manufactured with a low cost.

In the method, metal plating is preferably applied onto surfaces of the first leads and the second leads.

In such a manner, a substrate for an optical semiconductor apparatus having high reflectivity can be manufactured.

Moreover, the first leads and the second leads preferably each having a step, a taper portion, or a concave portion at their side surfaces in a thickness direction are used.

In this manner, the thermosetting resin composition can be held more surely in the gap during the injection molding so that the substrate can be readily manufactured. Also, the strength of the substrate can be improved.

Moreover, the first leads and the second leads may be arranged each in parallel by connecting the first leads and the second leads to a frame-shaped frame through a tie bar having a thickness thinner than a thicknesses of the first leads and the second leads.

In this manner, a substrate for an optical semiconductor apparatus that can be readily handled during the injection molding, and can reduce the generation of an unfilled portion and a resin burr in the resin molded body near the tie bar can be manufactured.

Moreover, the thermosetting resin composition used may be at least one selected from the group consisting of a silicone resin, an organic modified silicone resin, an epoxy resin, a modified epoxy resin, an acrylate resin and an urethane resin.

In this manner, a substrate for an optical semiconductor apparatus excellent in heat resistance can be manufactured.

Moreover, the cured thermosetting resin contains at least one selected from an inorganic filler and diffusing agent, the inorganic filler may be at least one selected from the group consisting of silica, alumina, magnesium oxide, antimony oxide, aluminum hydroxide, barium sulfate, magnesium carbonate and barium carbonate, and the diffusing agent may be at least one selected from the group consisting of barium titanate, titanium oxide, aluminum oxide and silicon oxide.

In this manner, a substrate for an optical semiconductor apparatus excellent in heat resistance, weather resistance and light resistance can be manufactured.

Furthermore, the present invention provides a method for manufacturing an optical semiconductor apparatus comprising mounting an optical semiconductor device on a first lead of the substrate for an optical semiconductor apparatus manufactured by the above method of the present invention, electrically connecting a first electrode and a second electrode of the optical semiconductor device to the first lead and a second lead, respectively, by wire bonding or flip chip bonding, and sealing the optical semiconductor device by a resin or subjecting the optical semiconductor device to lens molding.

According to the manufacturing method, an optical semiconductor apparatus which is excellent in heat dissipation properties, generates no unfilled portion and resin burr of the resin molded body and high quality can be manufactured with a low cost easily. In addition, when the optical semiconductor device is subjected to lens molding, a thin optical semiconductor apparatus which is reduced in the thickness can be manufactured.

In the method for manufacturing a substrate for an optical semiconductor apparatus of the present invention, a molded body of a thermosetting resin composition is molded by injection molding in a penetrating gap between the first leads and the second leads such that the substrate is formed in a plate shape and an exposed front surface and an exposed back surface of the first leads, the second leads and the resin molded body each tie in a same plane; therefore a substrate for an optical semiconductor apparatus that has excellent heat dissipation properties and high quality without the generation of an unfilled portion and a resin burr in the resin molded body and enables fabrication of a thin optical semiconductor apparatus can be readily manufactured with a low cost.

### BRIEF DESCRIPTION OF THE DRAWINGS

FIG. 1 is a schematic top view showing one example of the substrate for an optical semiconductor apparatus of the present invention;

FIG. 2 is a schematic sectional view in the straight line A-A′ direction of FIG. 1;

FIG. 3 is a schematic top view showing another example of the substrate for an optical semiconductor apparatus of the present invention;

FIG. 4 is an explanatory view of the injection molding in the method for manufacturing a substrate for an optical semiconductor apparatus of the present invention;

FIG. 5 is a schematic sectional view showing one example of the optical semiconductor apparatus of the present invention; and

FIG. 6 is an explanatory view of the method for manufacturing an optical semiconductor apparatus of the present invention.

### DETAILED DESCRIPTION OF THE PREFERRED EMBODIMENTS

In the following, embodiments of the present invention will be described but the present invention is not limited to these. embodiment

As stated above, there is a need for a method for manufacturing a substrate for an optical semiconductor apparatus that is excellent in heat dissipation properties, generates no unfilled portion and no resin burr of the resin molded body with good quality, and enables a thin optical semiconductor apparatus with good producibility and easily.

In view of this, the present inventors have earnestly studied to solve the above-mentioned problems. As a result, they have found that the above-mentioned problems can be solved by forming a substrate for an optical semiconductor apparatus into a plate shape by molding a molded body of a thermosetting resin composition between the first leads and the second leads without forming a reflector, and the resin molded body is molded by injection molding, whereby the present invention has been accomplished.

First, the substrate for an optical semiconductor apparatus of the present invention will be described.

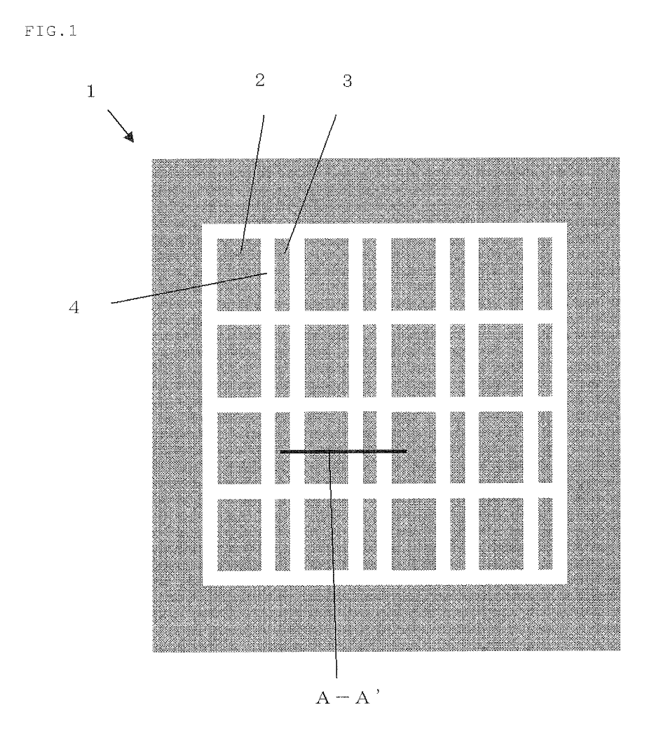

As shown in FIG. 1, the substrate 1 for an optical semiconductor apparatus of the present invention has first leads 2 and second leads 3 both made of a metal, and a molded body 4 of a thermosetting resin composition. The first leads 2 are to be electrically connected to the first electrodes of optical semiconductor devices through, for example, wires, and also serve as pads for mounting optical semiconductor devices. The second leads 3 are electrically connected to the second electrodes of the optical semiconductor devices through, for example, wires.

In the substrate 1 for an optical semiconductor apparatus, the first leads 2 and second leads 3 are each arranged in parallel.

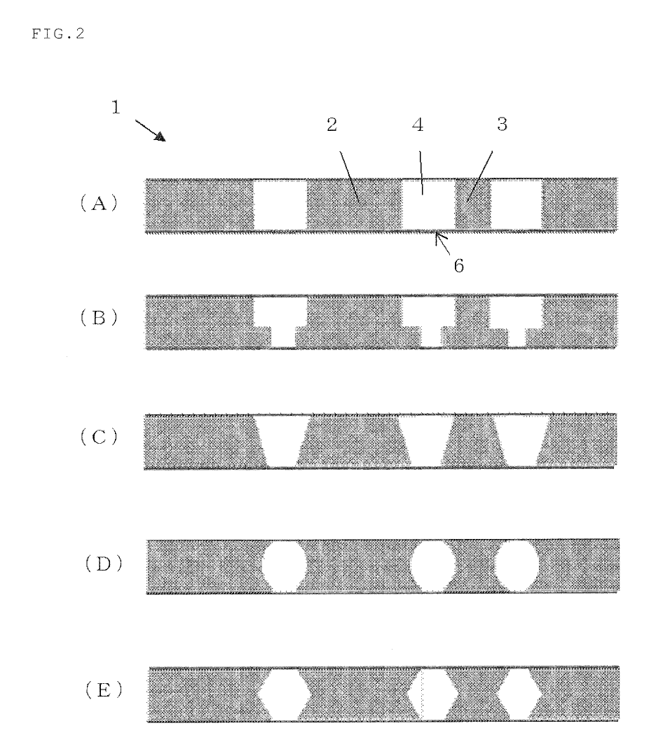

As shown in FIG. 2, the substrate 1 for an optical semiconductor apparatus has a so-called flat-flame structure in which a molded body 4 of the thermosetting resin composition is molded in a penetrating gap 6 between the respective first leads 2 and second leads 3 such that the substrate is formed in a plate shape and the exposed front surfaces of the first leads 2, the second leads 3 and the resin molded body 4 each lie in the same plane, and the exposed back surfaces of the first leads 2, the second leads 3 and the resin molded body 4 each lie in the same plane.

The molded body 4 of the thermosetting resin composition is molded by injection molding.

One of the reasons for employing such a plate structure is that, by providing the front and back surfaces of the substrate for an optical semiconductor apparatus lying substantially in the respective same planes, the fluidity of a lens material during lens molding in the manufacturing process of the optical semiconductor apparatus is not impaired and accordingly, it is possible to inhibit the generation of an unfilled portion of the lens material or a void in the lens. Furthermore, as compared with a substrate on which a reflector is mounted, there may be mentioned the point that the substrate 1 for an optical semiconductor apparatus of the present invention having no reflector enables reduction in the thickness of optical semiconductor apparatus.

The first leads 2 for mounting the optical semiconductor devices expose both their front and back surfaces so that heat generated from the optical semiconductor devices can be effectively emitted outside, resulting in excellent heat dissipation properties. For example, the back surface of the first leads 2 or the second leads 3 can be connected with an external electrode.

The resin molded body 4 is molded by injection molding, so that the substrate has high quality without an unfilled portion and a resin burr of the resin molded body 4 as mentioned below in detail.

Each of the first leads 2, which is not limited as long as it has an area capable of mounting an optical semiconductor devices, preferably has a wide area in the points of thermal conductivity, electro-conductivity and reflection efficiency. Accordingly, the distance between the first lead 2 and the second lead 3 is preferably 0.1 mm or more and 2 mm or less, more preferably 0.2 mm or more and 1 mm or less. When it is 0.1 mm or more, generation of an unfilled portion of the thermosetting resin can be inhibited. When it is 2 mm or less, an area for mounting the optical semiconductor device on the substrate can be sufficiently broadened.

It is preferred that metal plating is applied onto the surfaces of the first leads 2 and the second leads 3. According to this procedure, reflection efficiency of light emitted from the optical semiconductor devices can be enhanced. Also, in the fabrication of the optical semiconductor apparatus, when the optical semiconductor device is sealed by the thermosetting resin or subjected to lens-molding, adhesiveness between the thermosetting resin and the lens material can be also heightened.

The metal used for the plating may be conventionally known metal. In particular, silver, gold, palladium, aluminum and an alloy thereof can be used. Silver plating is preferably used since light can be most effectively reflected. These metal plating and alloy plating can be applied by conventional methods. The metal plating may have a single layer structure or a multilayer structure.

The thickness of the metal plating is generally in the range of 50 μm or less, preferably in the range of 10 μm or less. When it is 50 μm or less, it is economically advantageous. It is preferred to provide plating with high glossiness for the purpose of more enhancing the reflection efficiency of light emitted from the optical semiconductor devices. More specifically, it is preferred to have a glossiness of 1.0 or higher, more preferably 1.2 or higher. As the metal plating having such a high glossiness, a commercially available chemical solution for plating can be used by a conventionally known method.

On the surfaces of the first leads 2 and the second leads 3, first plating may be provided for the purpose of improving adhesiveness of the plating. As the first plating, silver plating, gold plating, palladium plating, nickel plating, copper plating, or a strike plating film thereof may be formed, but the present invention is not limited thereto. The film thickness of the first plating is generally in the range of 0.01 μm to 0.5 μm, preferably from 0.01 μm to 0.1 μm.

Further, a sulfuration-preventing treatment may be carried out on both the front and back surfaces of the first leads 2 and the second leads 3 to prevent metal sulfuration. This treatment is carried out to prevent light reflectance from lowering due to a change of color progressed by metal sulfuration as represented by silver plating. The sulfuration-preventing treatment may be carried out, for example, a method in which an alloy or a metal which can prevent sulfuration is plated on the uppermost surface of the leads, a method in which an organic resin is applied or coated on the uppermost surface of the leads with the extent to which wire bonding property is not deteriorated, a method in which a silane coupling agent such as a primer is applied or coated on the uppermost surface of the leads, or a method in which a glass film is arranged on the uppermost surface of the leads with the extent to which wire bonding property is not deteriorated, but the present invention is not limited to these methods and a conventionally known method can be used. The thickness of the sulfuration-preventing film is in a range in which wire bonding connection is not prevented and sulfuration can be prevented, and it is usually 1 μm or less, but the present invention is not particularly limited.

As shown in FIG. 2, the first leads and the second leads preferably each have a step (FIG. 2(B)), a taper portion (FIG. 2(C)), or a concave portion (at (D) and (E) in FIG. 2) at their side surfaces in the thickness direction. At (B) and (C) in FIG. 2, the steps and the taper portion have a shape extending outward in the direction from the front surface side to the back surface side of the substrate. At (D) and (E) in FIG. 2, the concave portion has a shape bending or curving toward the inside of the side surface. With the side surface having the step, taper portion or concave portion, the thermosetting resin filled at the time of injection molding can be so retained as to not drop from the substrate for an optical semiconductor apparatus.

At this time, it is preferred that the side surface has the step or concave portion, bending shape or curving shape in the viewpoint of increasing a contact area to surely hold the thermosetting resin, and the step is more preferable. The height of the step in the thickness direction is preferably in the range of 1/10(t) to ½(t) with respect to the total thickness (t) of the lead frame, more preferably in the range of ⅕(t) to ½(t). When the height of the step in the thickness direction is thinner than ½(t), it does not become a resistance to the flow of resin when the resin is filled at the time of injection molding, and generation of unfilling, void, and burr starting from the step can be inhibited. When the height of the step in the thickness direction is thicker than 1/10(t), the step do not deform due to insufficient strength and the handling thereof becomes easy.

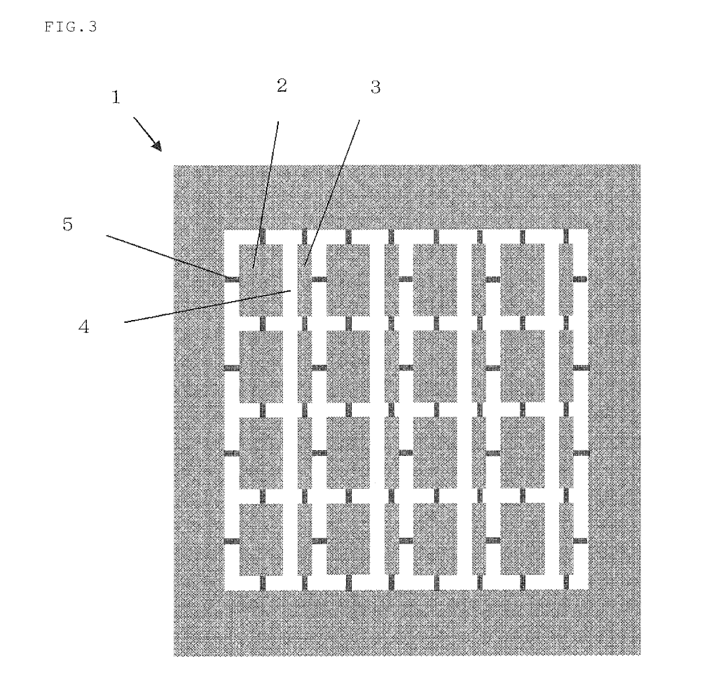

As shown in FIG. 3, the first leads 2 and the second leads 3 arranged each in parallel can be connected to a frame-shaped frame through a tie bar 5 having a thickness thinner than the thicknesses of the first leads and the second leads. More specifically, when the constitution of each one of the first leads 2 and the second leads 3, and the resin molded body 4 therebetween is represented as a unit frame, a plural number of the unit frames are connected by the tie bar 5 in the frame-shaped frame with each other in longitudinal and lateral directions to constitute a lead frame having a multi-unit-frame arrangement. Here, the tie bar 5 for connecting these may be either one or a plural number.

At this time, the thickness of the tie bar 5 is preferably in the range of 1/10(t) to ½(t) with respect to the total thickness (t) of the substrate for an optical semiconductor apparatus, more preferably ½(t) to ⅓(t). The portion at which the tie bar 5 is arranged is a flow passage through which the resin is filled at the time of injection molding. When the thickness is thinner than ½(t), it does not become a resistance to the flow of the resin, and generation of unfilling, void, and burr starting from the tie bar can be inhibited. When the thickness is thicker than 1/10(t), the strength to support the respective leads does not become insufficient and the handling of the lead frame becomes easy to be set and taken out from the mold at the time of molding.

The material of the first leads 2 and the second leads 3 may be copper, a copper alloy of a copper and a metal represented by nickel, zinc, chromium and/or tin is contained in copper, iron, or an iron alloy in which a metal represented by nickel, zinc, chromium and tin. A metal thin plate material, made of the above materials, formed by the conventionally used pressing or etching method can be used, but the present invention is not limited thereto. From the aspects of conductivity, heat dissipation, workability and economic efficiency, copper or the above copper alloy is preferably used. A commercially available product may be used as the above materials, preferably those having a conductivity of 30% TAGS or more, more preferably 50% IACS or more.

The thermosetting resin to be used for the resin molded body 4 is preferably at least one selected from the group consisting of a silicone resin, an organic modified silicone resin, an epoxy resin, a modified epoxy resin, an acrylate resin and a urethane resin. Among these, a silicone resin, an organic modified silicone resin, an epoxy resin and a modified epoxy resin are preferred, more preferably a silicone resin, or an organic modified silicone resin, and an epoxy resin. For example, when a thermoplastic resin represented by a polyamide or a liquid crystal polymer is used as a filling material, the thermoplastic resin after resin molding and the lead cannot be adhered. Therefore, it is not preferred since a gap is generated between the thermoplastic resin and the lead when expansion and shrinkage by heat of the substrate for an optical semiconductor apparatus are repeated.

The above-mentioned thermosetting resin may be a resin within the range which is capable of subjecting to injection molding, which may be either a liquid or a solid at the room temperature, and when it is a solid, it can be adjusted to a suitable viscosity capable of subjecting to injection molding by melting it using a special heating and mixing apparatus. In the viewpoint of heightening filling property of the thermosetting resin into a narrow portion, it is preferably a liquid material at room temperature, more preferably in the range of 1 to 100 Pa·s at room temperature. The thermosetting resin preferably has a light reflecting property, and a light reflectance at a wavelength of 450 nm after heat curing is preferably 80% or more, more preferably 90% or more.

The thermosetting resin is preferably those which become hard after curing to retain the shape of the lead frame, and it is preferably a resin excellent in heat resistance, weather resistance and light resistance. To have such a function depending on the purposes, it is preferred that at least one of an inorganic filler and a diffusing agent is added to the thermosetting resin composition to contain these in the cured product. The inorganic filler may be mentioned, for example, silica, alumina, magnesium oxide, antimony oxide, aluminum hydroxide, barium sulfate, magnesium carbonate and barium carbonate, and these materials may be used alone or in combination of two or more. In the aspects of thermal conductivity, light-reflecting characteristics, moldability, flame retardancy, it is preferably silica, alumina, antimony oxide or aluminum hydroxide. In addition, a particle size of the inorganic filler is not particularly limited, and when filling up efficiency with the diffusing agent, and fluidity and filling ability into the narrow portion of the thermosetting resin is considered, it is preferably 100 μm or less. The diffusing agent may be suitably used barium titanate, titanium oxide, aluminum oxide or silicon oxide. A particle size of the diffusing agent is not particularly limited, and when fluidity and filling ability into the narrow portion of the thermosetting resin is considered, it is preferably 100 μm or less.

In addition, depending on the purpose, at least one selected from the group consisting of a pigment, a fluorescent substance and a reflective substance may be mixed.

As these materials, for example, a material in a liquid state and to be used for silicone rubber injection molding is suitable, and there may be mentioned, for example, KEG-2000, KCR-3500 and KCR-4000 (product names), etc., which are products of Shin-Etsu Chemical Co., Ltd., but the present invention is not limited by these.

Next, the method for manufacturing the substrate for an optical semiconductor apparatus of the present invention will be described.

In the method for manufacturing a substrate for an optical semiconductor apparatus of the present invention, the substrate for an optical semiconductor apparatus of the present invention having first leads, second leads and a resin molded body is manufactured.

First, for example, as shown in FIG. 1, first leads 2 and second leads 3 are arranged each in parallel. At this time, as shown in FIG. 3, the first leads and the second leads can be prepared as a lead frame in which the leads are connected to a frame-shaped frame through a tie bar. This is preferable since handling of the first leads and the second leads becomes easy.

On the surfaces of the first leads 2 and the second leads 3, metal plating may be applied to enhance the reflection efficiency of light emitted from the optical semiconductor devices as mentioned above.

The metal plating may be formed not only the surfaces of the first leads 2 and the second leads 3 but also the entire surface of the first leads and the second leads. For example, a roll-to-roll method or a barrel plating method may be employed.

Incidentally, a sparger system in which a portion not necessary to conduct the plating is covered by a mechanical mask formed by a silicone rubber, etc., and a plating solution is blowing up to the portion to be plated, a taping system in which a masking tape is applied to a portion not necessary to conduct the plating, or an exposure system in which a resist is coated, etc., may be employed.

Next, a molded body 4 of the thermosetting resin composition is molded by injection molding in a penetrating gap between the first leads 2 and the second leads 3 such that the substrate is formed in a plate shape and an exposed front surface and an exposed back surface of the first leads 2, the second leads 3 and the resin molded body each tie in a same plane.

The distance between each of the first leads 2 and the second leads 3 is preferably 0.1 mm or more and 2 mm or less, and more preferably 0.2 mm or more and 1 mm or less, as mentioned above.

The injection molding is a molding method in which a liquid state resin or a melted resin is injected into the space (product portion) of the mold, and after solidifying it, the resultant product is taken out from the mold, in which the resin can be filled to a narrow portion even under a low pressure and no burr is generated to the product after the molding. Therefore, the injection molding can be preferably used in the present invention.

More specifically, in the flow passage of the resin in the molding method in which the first leads and the second leads are interposed between the upper mold and the lower mold, its width corresponds to the gap between the first leads and the second leads, and its thickness corresponds to the thickness of these leads, or when they are connected through the tie bar is used, the gap subtracted the thickness of the tie bar from the thickness of these leads. The thermosetting resin composition, which is a liquid state and has an extremely low viscosity, must be completely filled into such an extremely narrow gap without remaining voids, which can be accomplished only by using the injection molding.

In general, as the other molding method using the thermosetting resin, there is, for example, a transfer molding method, but this method is not suitably used for the manufacturing method in which the low viscosity resin is molded into the narrow portion like the present invention. When the low viscosity resin is molded by the transfer molding, the low viscosity resin leaks out from the plunger for pressing the resin and the minute gap of the mold so that good molding cannot be carried out. In addition, the transfer pressure is high so that the low viscosity thermosetting resin is oozed out from the minute gap between the leads and the upper and lower molds, and is then cured to become flash burr. When the flash burr is present on the lead surface, failure of the wire bonding in the wire bonding step of manufacture of the optical semiconductor apparatus, or causes soldering failure when mounting is carried out by soldering.

Also, when a high viscosity resin is subjected to transfer molding, the resin may be pressed under a higher pressure, but an unfilling portion and air remaining are generated in the narrow space; a flash burr is more likely generated. As a method for removing such a flash burr, there are a blast treatment represented by the jet scrubber and water jet, and a method of cleaning with an acid or an alkali, but in addition to lowering economic efficiency due to increase in the steps, a problem arises that these treatments impair metallic luster of the surface. This means that it directly links to lowering reflection efficiency of light, and causes reduction in brightness of the optical semiconductor apparatus whereby it is not preferred.

As the other molding method, for example, according to the compression molding, a low viscosity resin can be molded into the narrow portion as in the present invention, but due to the reason of the arrangement of the mold and a metal plate, it is impossible to prevent the resin from flowing into the back surface of the substrate, and the problem of flash burr is generated as in the transfer molding so that it cannot be applied.

The molding method of the resin molded body 4 by injection molding according to the present invention will be described below more specifically.

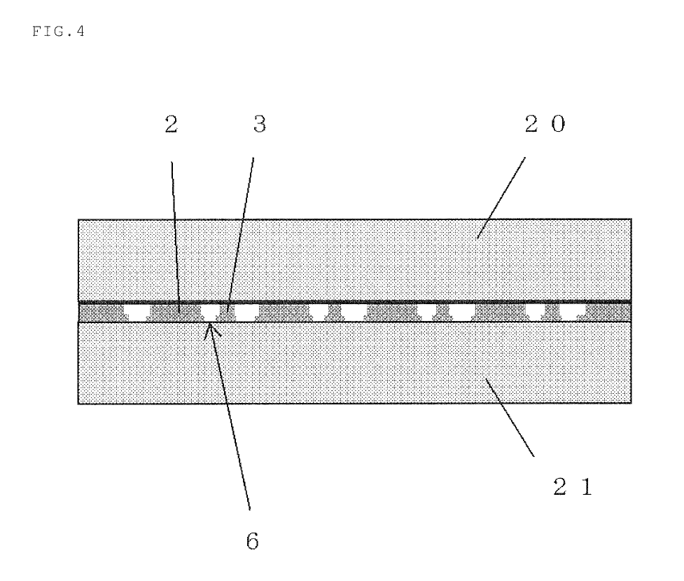

First, as shown in FIG. 4, the first and the second leads are arranged between the upper mold 20 and the lower mold 21.

As the injection molding, either of the insert molding method in which the first and the second leads are directly arranged in the upper and lower molds, and the thermosetting resin composition is injected from an resin inlet of one of the molds, or the in-mold molding method in which a release film is interposed between the molds and the first and the second leads may be used. The in-mold molding is more preferable.

In the case of the in-mold molding, by interposing release films among the respective gaps of the upper mold, the first and the second leads, and the lower mold, without remaining the minute gap between the first and the second leads and the molds, i.e., in the state of no gap into which the thermosetting resin can be entered between the leads and the molds, the molding can be carried out and further, the metal plating surface can be prevented from being damaged due to the clamping pressure of the molds during the molding.

The thermosetting resin composition injected into the mold is filled into the penetrating gap 6 between the first leads 2 and the second leads 3, and after curing it preferably under conditions of a temperature of 100° C. to 200° C. for 10 seconds to 300 seconds, the molds are opened and the substrate for an optical semiconductor apparatus formed into a plate shape is taken out. Then, depending on necessity, it may be further thermally cured under conditions of a temperature of 100° C. to 200° C. for 30 minutes to 10 hours for the purpose of completely curing the thermosetting resin.

Subsequently, depending on the purposes of degreasing and enhancing glossiness of the metal plating, cleaning of the substrate for an optical semiconductor apparatus or plating on the metal surface again may be carried out.

The flow passage (filling portion) of thermosetting resin during the injection molding may be any structure so long as it does not cause air remaining by occluding the thermosetting resin, and freely designed. Depending on necessity, any fabrication for the improvement of the finishing of the product may be added as providing a slit structure for the purpose of bleeding at around the bent.

According to the method for manufacturing the substrate for an optical semiconductor apparatus of the present invention, a substrate for an optical semiconductor apparatus which is excellent in heat dissipation properties, has high quality without an unfilled portion and a resin burr in the resin molded body can be readily manufactured. The substrate also enables fabrication of a thin optical semiconductor apparatus. According to the manufacturing method, a lead time for manufacturing the substrate can be shortened, and productivity can be improved by reducing the parts to be used. The substrate for an optical semiconductor apparatus manufactured by the method for manufacturing the substrate for an optical semiconductor apparatus of the present invention is excellent in mass productivity and reliability.

Next, the optical semiconductor apparatus of the present invention will be described.

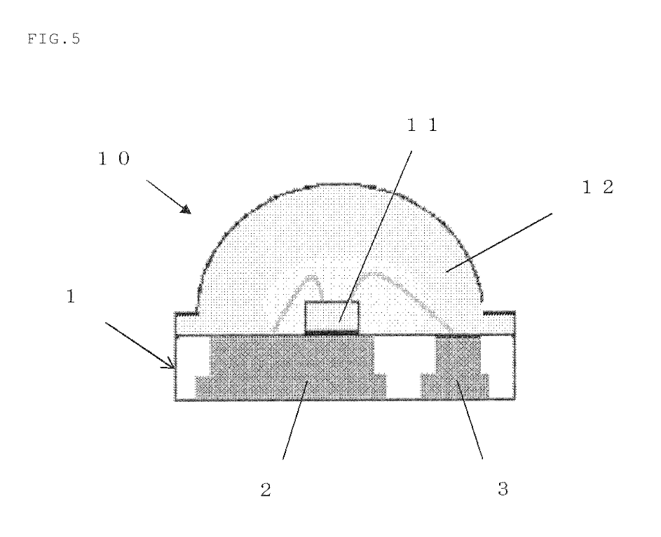

As shown in FIG. 5, in the optical semiconductor apparatus 10 of the present invention, an optical semiconductor device 11 is mounted on a first lead 2 of the substrate 1 for an optical semiconductor apparatus of the present invention, and the first electrode and the second electrode of the optical semiconductor device 11 are electrically connected to the first lead 2 and the second lead 3, respectively, by wire bonding or flip chip bonding. The optical semiconductor device 11 is lens molded by the lens material 12.

Such an optical semiconductor apparatus using the substrate for an optical semiconductor apparatus of the present invention is low-cost and has excellent heat dissipation properties and high quality without an unfilled portion and a resin burr of the resin molded body. In addition, the optical semiconductor device is lens molded and its thickness is reduced.

The optical semiconductor apparatus 10 of the present invention can be manufactured by the method for manufacturing an optical semiconductor apparatus of the present invention as described below.

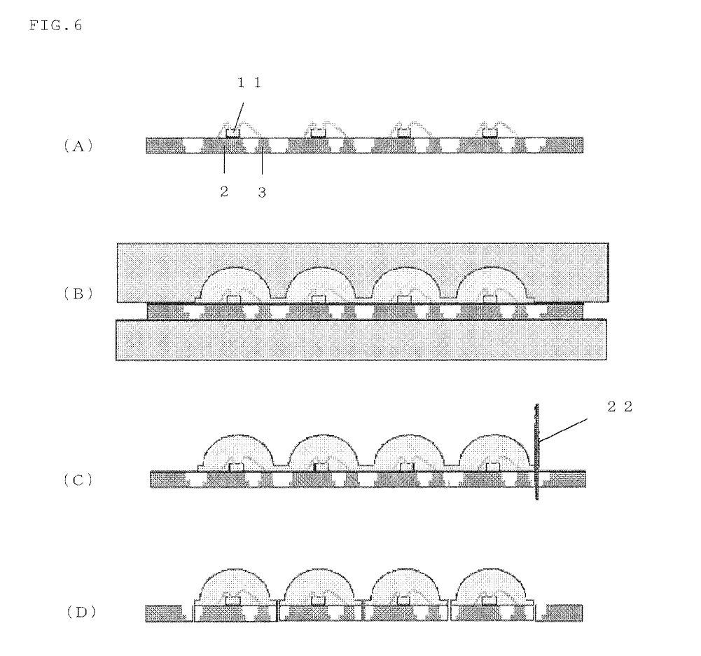

First, the optical semiconductor device 11 is mounted on a first lead 2 which also serves as a pad for mounting the optical semiconductor device 11 thereon (FIG. 6(A)).

The first electrode of the optical semiconductor device 11 with the first lead 2 is electrically connected. The second electrode of the optical semiconductor device 11 is electrically connected with the second lead 3. This connection is usually carried out by wire bonding, but may be carried out by flip chip bonding depending on the structure of the optical semiconductor device 11.

Depending on necessity, a photoconversion material may be coated on the optical semiconductor device 11. A conventionally known method may be used as the coating method, and it may be optionally selected from a dispensing method, a jet dispensing method, or adhesion of a film, and the like.

Lens molding or coating of a sealing resin is then carried out for the purpose of protecting the optical semiconductor device 11 and the wire (FIG. 6(B)). FIG. 6 shows an example in which lens molding is carried out. The lens molding can be carried out by using the conventionally known lens material, and in general, it is a thermosetting transparent material, and preferably a silicone resin for example. As a method of the lens molding, the conventionally known method such as transfer molding, injection molding and compression molding may be used. As the coating method of the sealing resin, there are a method of molding a lens material with a dome shape by using a dispensing method, and a method of coating an sealing resin to a concave portion formed by coating a dam material to an objective shape and cured by using the conventionally known method.

A shape of the material provided on the substrate for an optical semiconductor apparatus is not limited to a lens shape, and for example, it may be a trapezoidal shape, a convex shape or a square shape molded by transfer molding, injection molding, or compression molding, and then, divided into pieces. A method of lens molding, which can manufacture the products with the same shape within a short period of time and enables effective usage of brightness as an optical semiconductor apparatus, is preferable. The photoconversion material may be mixed in the resin of this procedure and then molded.

Next, depending on necessity, the optical semiconductor apparatus is cut by using a dicing blade 22, etc., to divide into pieces (FIG. 6(C)). According to this procedure, an optical semiconductor apparatus having one or more optical semiconductor devices can be obtained (FIG. 6(D)).

The cutting method may be employed the conventionally known method, and the apparatus can be cut by the conventionally know method such as a dicing process by a rotary blade, a laser processing, a water jet processing and a die processing, and the dicing process is preferred in the aspects of economy and industry.

### EXAMPLES

In the following, the present invention will be described more specifically with reference to Example of the present invention and Comparative Example, but the present invention is not restricted thereto.

### Example

### <Manufacture of Substrate for Optical Semiconductor Apparatus>

A metal plate of a copper alloy containing chromium-tin-zinc with a thickness of 0.3 mm was punched to prepare a lead frame, having a shape shown in FIG. 3, in which first leads and second leads were arranged each in parallel and connected through a tie bar. Also, an etching process was performed to form steps having a height in the thickness direction of 150 μm (½t) at the side surfaces of the first leads and the second leads, as shown at (B) in FIG. 2. Silver plating was then applied to the lead frame as metal plating. The glossiness of the metal plating was measured by using Micro Spectrophotometer VSS400A manufactured by NIPPON DENSHOKU INDUSTRIES Co., LTD. The measured points were five points, and its average value was obtained. As a result, the glossiness was 1.40.

Subsequently, for molding the thermosetting resin, in an injection molding machine capable of performing in-mold molding, the lead frame was fixed to the lower mold heated to 130° C. The lead frame was interposed with the upper mold heated similarly to 130° C. for mold clamping. As the thermosetting resin, KCR-3500 (product name), a liquid injection molding material, made by Shin-Etsu Chemical Co., Ltd., was used, and the thermosetting resin was injected from a nozzle of the injection molding machine. The injected thermosetting resin was heated in the mold at 130° C. for one minute to pre-cure the resin molded body. During the injection molding, no cured resin unnecessary for manufacture the substrate for an optical semiconductor apparatus was formed.

Next, the upper mold and the lower mold were opened, and the substrate for an optical semiconductor apparatus in which the lead frame and the thermosetting resin molded body were integrally molded was taken out from the mold. After taking out, the thermosetting resin molded body was further heated at 150° C. for 2 hours for complete curing to obtain a completed substrate for an optical semiconductor apparatus.

When the resin molded body of the obtained substrate for an optical semiconductor apparatus was examined, it was molded without an unfilled portion and air remaining of the thermosetting resin. Further, the silver plating had no damage on the surfaces of the first leads and the second leads, and the glossiness after molding was held at 1.4. Furthermore, when the front surface and the back surface of the first and the second leads were observed by a scanning electron microscope (SEM), no flash burr was seen.

### <Manufacture of Optical Semiconductor Apparatus>

Optical semiconductor devices were bonded by die bonding on the surface of the first leads of the substrate for an optical semiconductor apparatus of the present invention manufactured as mentioned above.

Then, the first electrodes of the optical semiconductor devices and the first leads of the substrate for an optical semiconductor apparatus, and the second electrodes of the optical semiconductor devices and the second leads of the substrate for an optical semiconductor apparatus were each electrically connected by wire bonding using wire bonders.

A silicone sealing agent (KER-2500 (product name), product of Shin-Etsu Chemical Co., Ltd.) into which 10% by volume of a photoconverting material (EG2762, product of INTEMATEX Corporation) was coated on the optical semiconductor devices equipped with the wires with a suitable amount, and cured.

For lens molding to the substrate for an optical semiconductor apparatus on which the optical semiconductor devices had been mounted with the photoconverting material, the substrate for an optical semiconductor apparatus was fixed to a lower mold, having a desired shape, heated to 150° C. in a transfer molding machine. The substrate for an optical semiconductor apparatus was interposed with the upper mold heated similarly to 150° C., for mold clamping. As a lens material, KER-2500 (product name), a silicone resin, made by Shin-Etsu Chemical Co., Ltd., was used, and injected from the plunger portion of the transfer molding machine. The injected silicone resin was heated in the mold at 150° C. for three minutes to pre-cure the same. Subsequently, the upper mold and the lower mold were opened, and the optical semiconductor apparatus was taken out from the mold.

After taking out, the thermosetting resin was further heated at 150° C. for 2 hours for complete curing to obtain an optical semiconductor apparatus on which a plurality of lens molded optical semiconductor devices had been mounted in a matrix state. When the lens material of the obtained optical semiconductor apparatus was examined, there was no unfilled portion or air remaining, and the lens was molded as designed. In addition, when the back surface of the optical semiconductor apparatus was observed by a scanning electron microscope (SEM), no flash burr was seen.

The portion of the resin molded body of the lens molded optical semiconductor apparatus was then cut together with the tie bar by the dicing process using a rotary blade to divide the optical semiconductor apparatus into pieces, and each piece was cleaned to obtain an optical semiconductor apparatus having an optical semiconductor device.

The obtained optical semiconductor apparatus was reduced in thickness and had high product-dimensional accuracy.

### Comparative Example

A substrate for an optical semiconductor apparatus was manufactured in the same manner as in Example except that the resin molded body was molded by transfer molding.

As a result, at the time of molding the resin molded body, a large amount of cured resin unnecessary for manufacturing the substrate for an optical semiconductor apparatus was formed. In addition, when the resin molded body after molding was examined, a large number of unfilled portions and air remaining were generated. To prepare this, the pressure at which the resin was pressed at the time of molding was increased, and the resin burr was generated on the lead surface instead.

It is to be noted that the present invention is not limited to the foregoing embodiment. The embodiment is just an exemplification, and any examples that have substantially the same feature and demonstrate the same functions and effects as those in the technical concept described in claims of the present invention are included in the technical scope of the present invention.

What is claimed is:

1. A substrate for an optical semiconductor apparatus for mounting optical semiconductor devices, the substrate comprising first leads to be electrically connected to first electrodes of the optical semiconductor devices and second leads to be electrically connected to second electrodes of the optical semiconductor devices, wherein
the first leads and the second leads are arranged each in parallel, a molded body of a thermosetting resin composition is molded by injection molding in a penetrating gap between the first leads and the second leads such that the substrate is formed in a plate shape, and an exposed front surface and an exposed back surface of the first leads, the second leads and the resin molded body each tie in a same plane.

2. The substrate for an optical semiconductor apparatus according to claim 1, wherein metal plating is applied onto surfaces of the first leads and the second leads.

3. The substrate for an optical semiconductor apparatus according to claim 1, wherein the first leads and the second leads each have a step, a taper portion or a concave portion at their side surfaces in a thickness direction.

4. The substrate for an optical semiconductor apparatus according to claim 2, wherein the first leads and the second leads each have a step, a taper portion or a concave portion at their side surfaces in a thickness direction.

5. The substrate for an optical semiconductor apparatus according to claim 1, wherein the first leads and the second leads arranged each in parallel are connected to a frame-shaped frame through a tie bar having a thickness thinner than the thicknesses of the first leads and the second leads.

6. The substrate for an optical semiconductor apparatus according to claim 4, wherein the first leads and the second leads arranged each in parallel are connected to a frame-shaped frame through a tie bar having a thickness thinner than the thicknesses of the first leads and the second leads.

7. The substrate for an optical semiconductor apparatus according to claim 1, wherein the thermosetting resin composition is at least one selected from the group consisting of a silicone resin, an organic modified silicone resin, an epoxy resin, a modified epoxy resin, an acrylate resin and an urethane resin.

8. The substrate for an optical semiconductor apparatus according to claim 6, wherein the thermosetting resin composition is at least one selected from the group consisting of a silicone resin, an organic modified silicone resin, an epoxy resin, a modified epoxy resin, an acrylate resin and an urethane resin.

9. The substrate for an optical semiconductor apparatus according to claim 1, wherein the cured thermosetting resin contains at least one of an inorganic filler and a diffusing agent, the inorganic filler is at least one selected from the group consisting of silica, alumina, magnesium oxide, antimony oxide, aluminum hydroxide, barium sulfate, magnesium carbonate and barium carbonate, and the diffusing agent is at least one selected from the group consisting of barium titanate, titanium oxide, aluminum oxide and silicon oxide.

10. The substrate for an optical semiconductor apparatus according to claim 8, wherein the cured thermosetting resin contains at least one of an inorganic filler and a diffusing agent, the inorganic filler is at least one selected from the group consisting of silica, alumina, magnesium oxide, antimony oxide, aluminum hydroxide, barium sulfate, magnesium carbonate and barium carbonate, and the diffusing agent is at least one selected from the group consisting of barium titanate, titanium oxide, aluminum oxide and silicon oxide.

11. An optical semiconductor apparatus comprising an optical semiconductor device mounted on a first lead of the substrate for an optical semiconductor apparatus according to claim 1, a first electrode and a second electrode of the optical semiconductor device are electrically connected to the first lead and a second lead, respectively, by wire bonding or flip chip bonding, and the optical semiconductor device is sealed by a resin or subjected to lens molding.

12. An optical semiconductor apparatus comprising an optical semiconductor device mounted on a first lead of the substrate for an optical semiconductor apparatus according to claim 10, a first electrode and a second electrode of the optical semiconductor device are electrically connected to the first lead and a second lead, respectively, by wire bonding or flip chip bonding, and the optical semiconductor device is sealed by a resin or subjected to lens molding.

13. A method for manufacturing a substrate for an optical semiconductor apparatus for mounting optical semiconductor devices, the substrate including first leads to be electrically connected to first electrodes of the optical semiconductor devices and second leads to be electrically connected to second electrodes of the optical semiconductor devices, the method comprising
arranging the first leads and the second leads each in parallel, and
molding a molded body of a thermosetting resin composition by injection molding in a penetrating gap between the first leads and the second leads such that an exposed front surface and an exposed back surface of the first leads, the second leads and the resin molded body each tie in a same plane and the substrate is formed in a plate shape.

14. The method for manufacturing a substrate for an optical semiconductor apparatus according to claim 13, wherein metal plating is applied onto surfaces of the first leads and the second leads.

15. The method for manufacturing a substrate for an optical semiconductor apparatus according to claim 13, wherein the first leads and the second leads each having a step, a taper portion, or a concave portion at their side surfaces in a thickness direction are used.

16. The method for manufacturing a substrate for an optical semiconductor apparatus according to claim 14, wherein the first leads and the second leads each having a step, a taper portion, or a concave portion at their side surfaces in a thickness direction are used.

17. The method for manufacturing a substrate for an optical semiconductor apparatus according to claims 13, wherein the first leads and the second leads are arranged each in parallel by connecting the first leads and the second leads to a frame-shaped frame through a tie bar having a thickness thinner than a thicknesses of the first leads and the second leads.

18. The method for manufacturing a substrate for an optical semiconductor apparatus according to claims 16, wherein the first leads and the second leads are arranged each in parallel by connecting the first leads and the second leads to a frame-shaped frame through a tie bar having a thickness thinner than a thicknesses of the first leads and the second leads.

19. The method for manufacturing a substrate for an optical semiconductor apparatus according to claim 13, wherein the thermosetting resin composition used is at least one selected from the group consisting of a silicone resin, an organic modified silicone resin, an epoxy resin, a modified epoxy resin, an acrylate resin and an urethane resin.

20. The method for manufacturing a substrate for an optical semiconductor apparatus according to claim 18, wherein the thermosetting resin composition used is at least one selected from the group consisting of a silicone resin, an organic modified silicone resin, an epoxy resin, a modified epoxy resin, an acrylate resin and an urethane resin.

21. The method for manufacturing a substrate for an optical semiconductor apparatus according to claim 13, wherein the cured thermosetting resin contains at least one selected from an inorganic filler and diffusing agent, the inorganic filler is at least one selected from the group consisting of silica, alumina, magnesium oxide, antimony oxide, aluminum hydroxide, barium sulfate, magnesium carbonate and barium carbonate, and the diffusing agent is at least one selected from the group consisting of barium titanate, titanium oxide, aluminum oxide and silicon oxide.

22. The method for manufacturing a substrate for an optical semiconductor apparatus according to claim 20, wherein the cured thermosetting resin contains at least one selected from an inorganic filler and diffusing agent, the inorganic filler is at least one selected from the group consisting of silica, alumina, magnesium oxide, antimony oxide, aluminum hydroxide, barium sulfate, magnesium carbonate and barium carbonate, and the diffusing agent is at least one selected from the group consisting of barium titanate, titanium oxide, aluminum oxide and silicon oxide.

23. A method for manufacturing an optical semiconductor apparatus comprising
mounting an optical semiconductor device on a first lead of the substrate for an optical semiconductor apparatus manufactured by the method according to claim 13,
electrically connecting a first electrode and a second electrode of the optical semiconductor device to the first lead and a second lead, respectively, by wire bonding or flip chip bonding, and
sealing the optical semiconductor device by a resin or subjecting the optical semiconductor device to lens molding.

24. A method for manufacturing an optical semiconductor apparatus comprising
mounting an optical semiconductor device on a first lead of the substrate for an optical semiconductor apparatus manufactured by the method according to claim 22,
electrically connecting a first electrode and a second electrode of the optical semiconductor device to the first lead and a second lead, respectively, by wire bonding or flip chip bonding, and
sealing the optical semiconductor device by a resin or subjecting the optical semiconductor device to lens molding.
